(19) United States
(12) Patent Application Publication
(10) Pub. No.: US 2002/0038990 A1
(43) Pub. Date: Apr. 4, 2002

(54) Piezoelectric composite device and method for making same

(75) Inventors: Garnett C. Horner, Hampton, VA (US); John Edward Teter JR., Hampton, VA (US); William Eugene Robbins, Achilles, VA (US); Benjamin M. Copeland, Carrollton, VA (US)

Correspondence Address: NASA Langley Research Center, Mail Stop 212, Hampton, VA, 23681-2199, US

(73) Assignee: National Aeronautics and Space Administration

(21) Appl. No.: 09/932,872

(22) Filed: Aug. 17, 2001

Related U.S. Application Data
(60) Provisional application No. 60/226,729, filed on Aug. 18, 2000.

(51) Int. Cl. H01L 41/04

(52) U.S. Cl. 310/363; 310/364; 310/365

(57) ABSTRACT

The present invention includes a method of fabricating a piezoelectric composite device comprising steps of (a) disposing a first layer of electrically non-conductive film over the first layer of tape; (b) disposing a first electrically conductive lead over the first layer of electrically non-conductive film; (c) disposing a piezoelectric wafer over the first electrically conductive lead and the first layer of electrically non-conductive film; (d) disposing a second electrically conductive lead over the piezoelectric wafer; (e) disposing a second electrically non-conductive film over the second electrically conductive lead and the wafer, wherein the layers of electrically non-conductive film, the electrically conductive leads, and the wafer form a laminate assembly; and (f) consolidating the laminate assembly at a predetermined temperature and pressure. The present invention also comprises a highly flexible piezoelectric composite device made by a thermoplastic process that consolidates the laminate assembly and forms a hermetic seal.

### ORIGIN OF THE INVENTION

The invention described herein was made by employees of the United States Government and may be used by or for the Government for governmental purposes without the payment of any royalties thereon or therefor.

### BACKGROUND OF THE INVENTION

The present invention is generally related to piezoelectric composite devices and to methods of fabricating piezoelectric composite devices.

### SUMMARY OF THE INVENTION

The present invention is directed to, in one aspect, a method of fabricating a piezoelectric composite device, comprising the steps of (a) providing a first layer of electrically non-conductive film, (b) disposing a first electrically conductive lead over the first layer of electrically non-conductive film, (c) disposing a piezoelectric wafer over the first electrically conductive lead and the first layer of electrically non-conductive film, (d) disposing a second electrically conductive lead over the piezoelectric wafer, (e) disposing a second electrically non-conductive film over the second electrically conductive lead and the wafer, (f) retaining the films, leads and wafer in predetermined positions, wherein the layers of electrically non-conductive film, the electrically conductive leads and the wafer form a laminate assembly, and (g) consolidating the laminate assembly at a predetermined temperature and pressure.

In one embodiment, the step for consolidating the laminate assembly comprises providing a substantially flat plate, placing the laminate assembly on the plate, covering the laminate assembly with an electrically non-conductive material and sealing the material to the periphery of the plate to form an air-tight seal, forming an opening in the material to allow venting of gasses, providing an air-tight pressure chamber, inserting the plate with the laminate assembly thereon into the chamber, controlling the chamber to provide a predetermined pressure at a predetermined temperature, maintaining the predetermined pressure and temperature for a predetermined amount of time, and controlling the chamber to release the vacuum and reduce the pressure and to reduce the temperature to approximately room temperature.

In yet another aspect, the present invention is directed to a piezoelectric composite device comprising a piezoelectric wafer having a first side and a second side, a first electrically conductive lead having a portion thereof positioned on the first side of the wafer, a second electrically conductive lead having a portion thereof positioned on the second side of the wafer; and a layer of electrically non-conductive film encapsulating the wafer and the portions of the electrically conductive leads so as to effect electrical contact between the first and second leads with the first and second sides, respectively, of the wafer. The wafer is hermetically sealed and highly flexible, enabling it to be mounted over or wrapped around curved surfaces having a radius of curvature of 0.25 inches or more in the region where the piezoelectric wafer is encased.

### BRIEF DESCRIPTION OF THE DRAWINGS

The features of the invention are believed to be novel and the elements characteristic of the invention are set forth with particularity in the appended claims. The figures are for illustration purposes only and are not drawn to scale. The invention itself, however, both as to organization and method of operation, may best be understood by reference to the detailed description which follows taken in conjunction with the accompanying drawings in which:

FIG. 1 is an exploded, side view of a piezoelectric device made in accordance with the method of the present invention.

FIG. 2 is an end view taken along line 2-2 of FIG. 1.

FIG. 3 is a cross sectional view of the resulting piezoelectric composite device fabricated in accordance with the present invention.

FIG. 4 is a top plan view of the resulting piezoelectric composite device fabricated in accordance with the present invention.

FIG. 5 is a schematic flow diagram showing a method of manufacturing a piezoelectric device in accordance with one embodiment of the present invention.

FIGS. 6A and 6B show perspective views of two embodiments of the present invention.

FIG. 7 shows one embodiment of the present invention mounted upon a curved surface.

FIG. 8 shows one embodiment of the present invention mounted upon a three-dimensional curved surface.

FIG. 9 shows seven embodiments of the present invention after each had been wrapped around a curved surface.

### DETAILED DESCRIPTION OF THE INVENTION

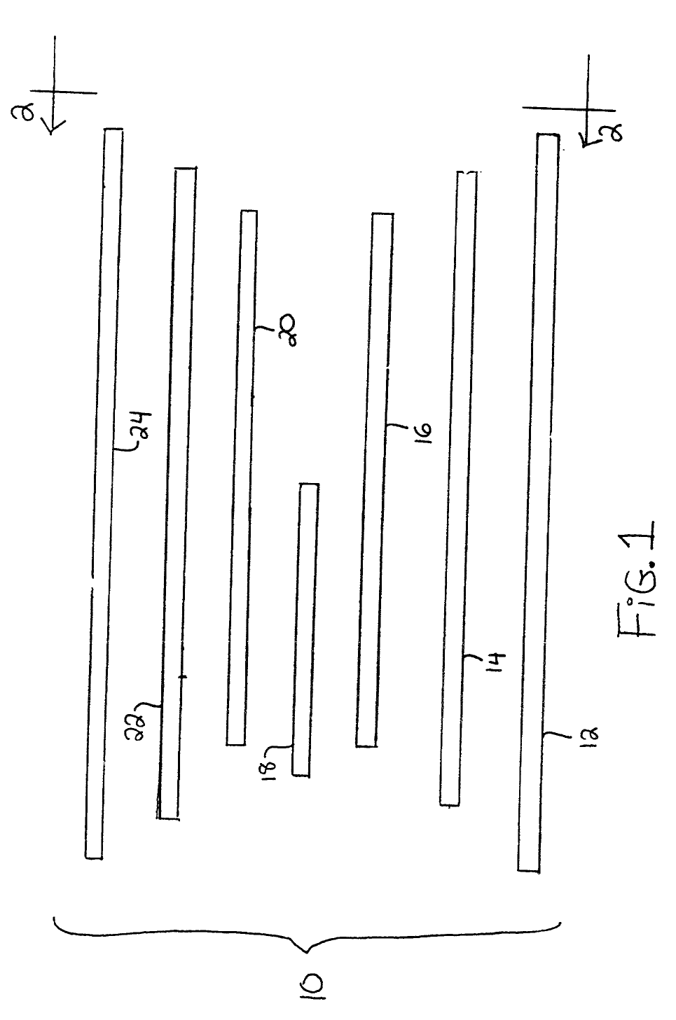

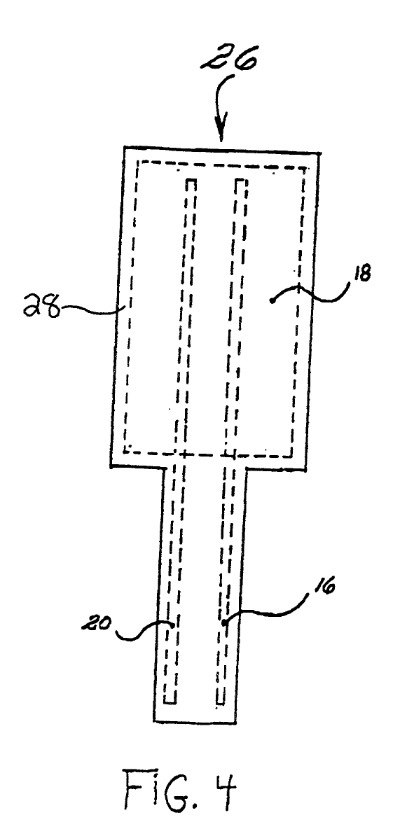

In describing the embodiments of the present invention, reference will be made herein to FIGS. 1-9 of the drawings in which like numerals refer to like features of the invention. The present invention is an improvement to the packaged strain actuator disclosed in U.S. Pat. No. 5,656,882, which is hereby incorporated by reference. The present invention is also an improvement to the electroactive assembly disclosed in U.S. Pat. No. 5,857,694, which is also incorporated by reference.

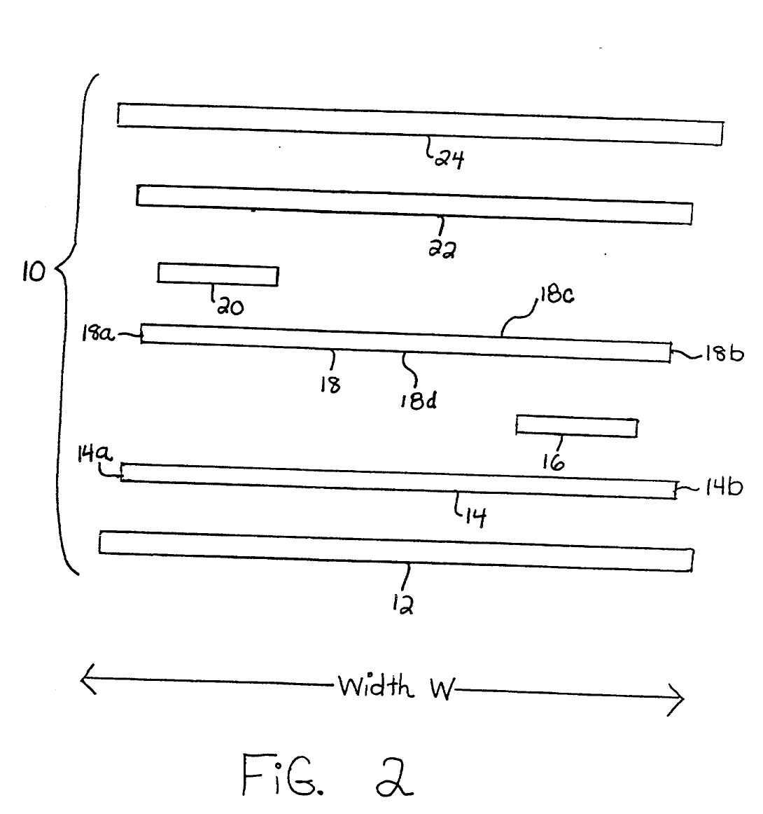

The ensuing description and FIGS. 1-5 describe the method of the present invention. FIG. 2 is an end view that shows the width W of each laminate (or component) with respect to the other laminates. It is to be understood that such widths of the laminates pertain to just one embodiment of the present invention and that laminates having other widths may be used as well. Furthermore, it is to be understood that although the shapes of the particular laminates are shown to be a generally rectangular planform, the laminates can be configured to have other planform shapes as well such as square, triangular, circular, oval, etc. The assembly of laminates from which the piezoelectric composite device is fabricated is indicated by numeral 10.

In order to facilitate understanding of the method of the present invention, each step of the aforementioned method is described in detail.

(a) The method may begin by providing a fixture, mold, or jig for aligning the specific components used to fabricate the piezoelectric composite device. The size of the fixture, mold, or jig depends upon the size of the individual components used to fabricate the piezoelectric composite device. The fixture, mold, or jig comprises a surface for receiving the stack of assembled components. It is to be understood that the use of a fixture, mold, or jig pertains to just one embodiment of the present invention. Other alignment methods and apparatuses may be used to position and align the specific components used to fabricate the piezoelectric composite device or no fixture, mold, or jig may be used.

All components and laminates should be free of oil and grease including fingerprints and dirt particles so as to prevent contamination of the piezoelectric composite device.

(b) In one embodiment, the second step of the method of the present invention entails disposing a layer of electrically non-conductive tape 12 on the mold surface. Tape 12 is positioned on the mold surface such that the adhesive side is face up. Tape 12 is thermally stable and removable after processing. In one embodiment, tape 12 is configured as Kapton® tape manufactured by The DuPont™ Company. The actual dimensions of tape 12 depend upon the size of the mold and of the desired piezoelectric composite device. In one embodiment, tape 12 has a width of about 2 inches and a thickness of about 0.001 inch. Tape 12 helps prevent movement of other laminate layers placed on top of it and facilitates proper alignment of these layers.

(c) Next, electrically non-conductive film 14 is disposed over the adhesive side of tape 12. The adhesive side of tape 12 prevents movement of film 14 and facilitates alignment of film 14 in a predetermined position. In one embodiment, film 14 is configured as a polyimide film that has a predetermined Coefficient of Thermal Expansion (CTE) and a predetermined glass transition temperature, or T_{g}. In one embodiment, film 14 is configured as DuPont™ 200 Kapton® EKJ film. This film is a self-adhering composite comprising a layer of polyimide adhesive on both sides of the film. The particular film used has a core of about 0.001 inch Kapton® E with about a 0.0005 inch layer of a thermoplastic polyimide adhesive DuPont™ Kapton® KJ on each side of the Kapton® E to provide a total thickness of about 0.002 inch. In an alternate embodiment, film 14 is configured as DuPont™ Kapton® KJ thermoplastic film instead of DuPont™ 200 Kapton® EKJ film. As is understood by the skilled artisan, Kapton® KJ is a thermoplastic polyimide film designed to function as a bonding sheet for high-temperature constructions. In one embodiment, the length and width of film 14 are less than that of tape 12 (see FIGS. 1 and 2). The film includes ends 14a and 14b.

As mentioned previously, film 14 has a predetermined CTE and T_{g}. For instance, Dupont™ Kapton® EKJ polyimide film has a CTE of approximately 25 ppm/° C. Further, the T_{g} for the adhesive portion of this film is 220° C., whereas the T_{g} of the Kapton® E core is greater than 340° C. On the other hand, Dupont™ Kapton® KJ polyimide film has a CTE of approximately 60 ppm/° C. and a T_{g} of 220° C.

(d) The next step entails disposing a first electrically conductive lead 16 over film 14. In one embodiment, the length and width of lead 16 is less than the length and width, respectively, of film 14. In one embodiment, conductive lead 16 is fabricated from nickel ribbon. In another embodiment, annealed nickel is used. In one embodiment, the conductive lead 16 has a thickness and width of about 0.001 inch and 0.120 inch, respectively. However, lead 16 can be fabricated from other materials of good electrical conductivity, e.g. copper, silver, gold, Inconel, carbon fiber, etc. The position of lead 16 shown in FIGS. 1-4 is just one possible position. Lead 16 can extend from wafer 18 in other directions as well.

(e) Next, piezoelectric wafer 18 is disposed over lead 16 and film 14. Wafer 18 has widthwise ends 18a and 18b. Wafer 18 can have any suitable length, width and thickness dimensions. In one embodiment, wafer 18 has a thickness of about 0.008 inch. In one embodiment, piezoelectric wafer 18 is electroded, i.e., it has a uniform surface deposited with an electrically conductive material, such as nickel. In another embodiment, wafer 18 has a width that is less than film 14. As shown in FIG. 2, lead 16 contacts a portion of wafer 18 that is in proximity to end 18b. In another embodiment, wafer 18 can also be configured to have interdigitated electrodes or other electrically conductive patterns formed thereon rather than a uniform surface electroding. In one embodiment, piezoelectric wafer 18 is made of piezoelectric material such as lead zirconate titanate (PZT) having a predetermined CTE of 4 ppm/° C. and a Curie temperature of approximately 350 to 365° C. In another embodiment wafer 18 is made of electrostrictive material.

(f) The next step entails disposing a second electrically conductive lead 20 over wafer 18. In one embodiment, lead 20 has generally the same length and width dimensions as that of lead 16 and is fabricated from nickel ribbon. In another embodiment, annealed nickel is used. However, lead 20 can be fabricated from other materials, e.g. copper, silver, gold, Inconel, carbon fiber, etc. In one embodiment, the conductive lead 20 has a thickness and width of about 0.001 inch and 0.120 inch, respectively. As shown in FIG. 2, lead 20 is positioned on the portion of wafer 18 that is in proximity to end 18a. The position of lead 20 shown in FIGS. 1-4 is just one possible position. Lead 20 can extend from wafer 18 in other directions as well.

(g) Next, electrically non-conductive film 22 is disposed over wafer 18 and lead 20. In one embodiment, film 22 has a width that is greater than the width of lead 20. In one embodiment, film 22 has a length and width that are generally the same as that of film 14. In one embodiment, film 22 is a polyimide film as described in the foregoing description having a predetermined CTE and T_{g}.

(h) In one embodiment, the next step comprises disposing a layer of electrically non-conductive adhesive tape 24 over film 22 such that the adhesive side of the tape contacts film 22. As with tape 12, tape 24 is thermally stable and removable after final processing. In one embodiment, tape 24 has a width and length that is greater than the width and length, respectively, of film 22. In a preferred embodiment, tape 24 is configured as Kapton® tape which was described in the foregoing description. In one embodiment, tape 24 has a thickness that is about 0.001 inch. The adhesive side of tape 24 hinders movement of the previously disposed laminates and facilitates alignment of these laminates in a predetermined position.

(i) In one embodiment, the next step entails trimming any excess amounts of tape 12 and 24 and film 14 and 22 from assembly 10. Assembly 10 is then removed from the fixture, mold, or jig (if used). Additional tape may be used to secure the assembly in the desired configuration. Assembly 10 is then positioned on a substantially flat metal surface (not shown) such as a metal plate. This step may not be necessary depending upon how tape layers 12 and 24 and film layers 14 and 22 were formed in the previous steps.

(j) The next step entails “bagging” assembly 10. This step comprises placing a “bag” fabricated from an electrically non-conductive material over assembly 10 and around the perimeter of the metal plate. In one embodiment, the electrically non-conductive material disposed over assembly 10 is configured from Kapton®. A sealant around the periphery of the Kapton® “bag” provides an airtight seal at the perimeter of the metal plate. An opening is then formed in the Kapton® “bag” for use in a consolidating process described in the next step (k). In an alternate embodiment, a sheet of fiberglass cloth is first placed over assembly 10 before the Kapton® “bag” is disposed over assembly 10 and sealed to the periphery of the metal plate.

(k) Next, assembly 10 is consolidated. In one embodiment, this step for consolidating comprises vacuum sealing and pressure heating the assembly 10. In order to vacuum seal and pressure heat the assembly 10, the metal plate containing the assembly 10 is placed into an autoclave. In one embodiment, the autoclave is manipulated according to the following steps:

(1) the pressure of the autoclave is configured to initially provide a pressure of 15 pounds per square inch (psi) and ambient room temperature, e.g. 20° C. The autoclave is further configured to provide a 10° C. per minute increase in temperature until 325° C. is attained;

(2) thereafter, the autoclave is configured to provide a pressure of 300 psi;

(3) the autoclave temperature of 325° C. and pressure of 300 psi are maintained for about 2 hours;

(4) thereafter, the autoclave temperature is reduced to about 200° C. wherein the vacuum and pressure are released;

(5) thereafter, the autoclave temperature is allowed to decrease to room temperature; and

(6) the metal plate with assembly 10 thereon is removed from the autoclave and tape layers 12 and 24 are removed.

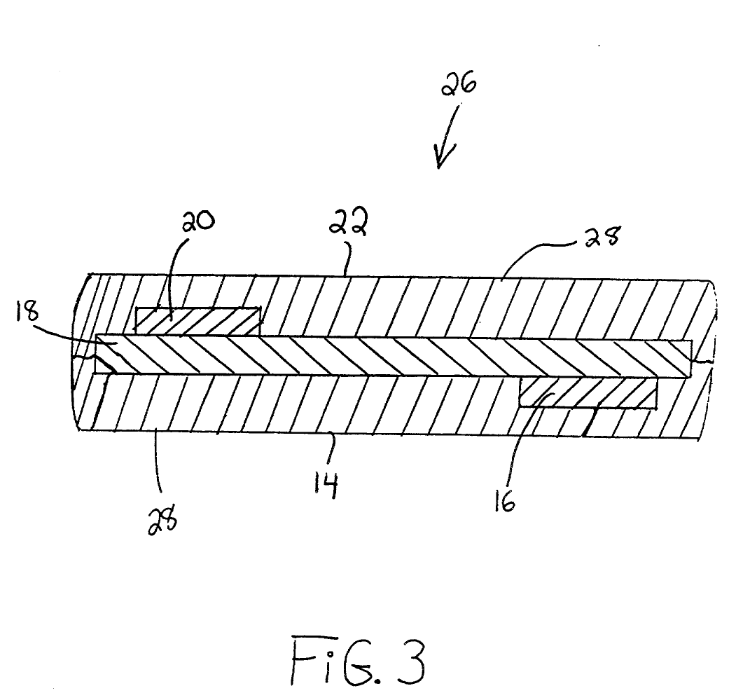

The temperature and pressure settings of the autoclave may be varied depending upon the type of materials from which wafer 18 and films 14 and 22 are fabricated. The temperatures should be equal or greater to the T_{g} of the films 14 and 22, to ensure the films melt and have a viscous flow over the leads 16 and 20 and the ends 18a and 18b of the wafer 18, thereby creating an encapsulating layer 28 as shown in FIG. 3.

Tape layers 12 and 24 are just one technique for maintaining films 14 and 22, leads 16 and 20, and wafer 18 in alignment and preventing movement of these laminates (or components) before the step for consolidating. Other techniques can be used to maintain films 14 and 22, leads 16 and 20, and wafer 18 in alignment. For example, an adhesive can be applied to films 14 and 22, leads 16 and 20, and wafer 18 to maintain their alignment and prevent movement of these components.

Vacuum sealing is only one example of the step for consolidating assembly 10. In another embodiment, a hot press may be used instead of an autoclave. In such an embodiment, “bagging” assembly 10 is not necessary. When a hot press is used, the step for consolidating the laminate assembly 10 comprises the following steps: (1) clean the platens of the hot press and align them to be parallel and flat; (2) cover the bottom platen with a high temperature cloth; (The high temperature cloth is made of Teflon® fibers, which is based on the chemical substance of Polytetrafluorethylene (PTFE)); (3) place the laminate assembly 10 on the Teflon® cloth; (4) cover laminate assembly 10 with another piece of Teflon® cloth; (5) cover the laminate assembly 10 and the second piece of Teflon® cloth with a rubber sheet; (6) heat the laminate assembly to 325° C.; (7) apply 300 psi of pressure; (8) hold the temperature and pressure for 30 minutes; (9) cool to ambient room temperature; (10) remove the pressure; and (11) remove the laminate assembly 10 from the press.

The temperature and pressure settings of the hot press may be varied depending upon the type of materials from which wafer 18 and films 14 and 22 are fabricated. The temperatures should be equal or greater to the T_{g} of the films 14 and 22, to ensure the films melt and have a viscous flow over the leads 16 and 20 and the ends 18a and 18b of the wafer 18, thereby creating an encapsulating layer 28.

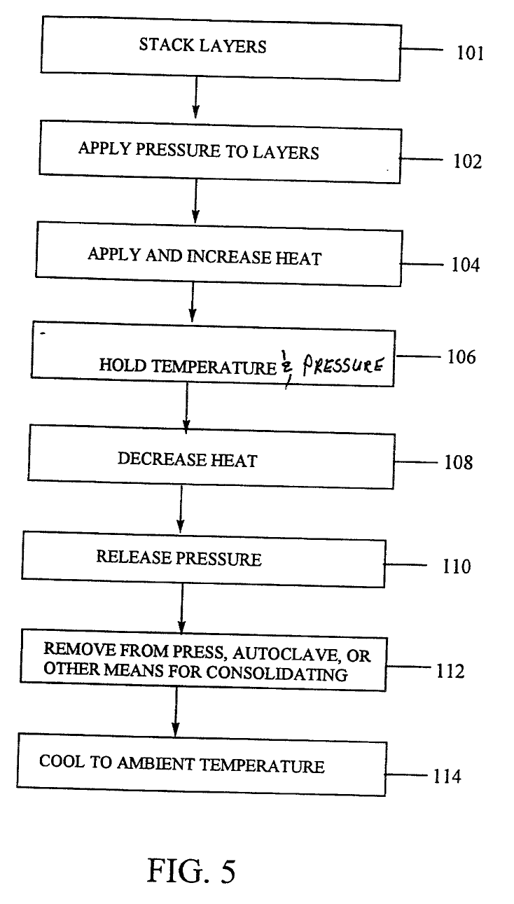

FIG. 5 illustrates a summary of the basic sub-steps comprising the step for consolidating the laminate assembly 10. These sub-steps comprise stacking the laminate layers; applying pressure to the laminate layers; applying and increasing heat; holding the temperature and pressure; decreasing the heat; releasing the pressure; removing the laminate layers from the hot press, autoclave, or other means for consolidating; and cooling the laminate layers to room temperature.

The step for consolidating melts films 14 and 22 to form a single encapsulating layer 28 that is bonded to wafer 18 and leads 16 and 20. Encapsulating layer 28 presses conductive leads 16 and 20 against wafer 18 such that leads 16 and 20 and wafer 18 are totally encapsulated in the polyimide film. As a result, the device 26 is hermetically sealed and may be embedded into conductive materials such as graphite epoxy composite. The device 26 may also be positioned upon or in between pre-impregnated fabrics (i.e. fabrics pre-impregnated with epoxy) such that the conductive leads extend from the encapsulating layer (around the leads and the wafer) and beyond the fabric. Further, the conductive leads 16 and 20 are electrically insulated within the device 26.

Referring now to FIGS. 3, 4, 6A, and 6B, various embodiments of a flexible piezoelectric composite device 26, the product of the method of the present invention are shown. In one embodiment, indicated in FIGS. 3, 4, and 6A, films 14 and 22 have the same CTE with respect to each other but a different CTE than that of wafer 18. With this embodiment, the initial compressive stress placed on the wafer 18 during the step for consolidating is substantially equal on the top surface 18c and the bottom surface 18d of the wafer, resulting in a substantially flat device 26 in the x-y plane.

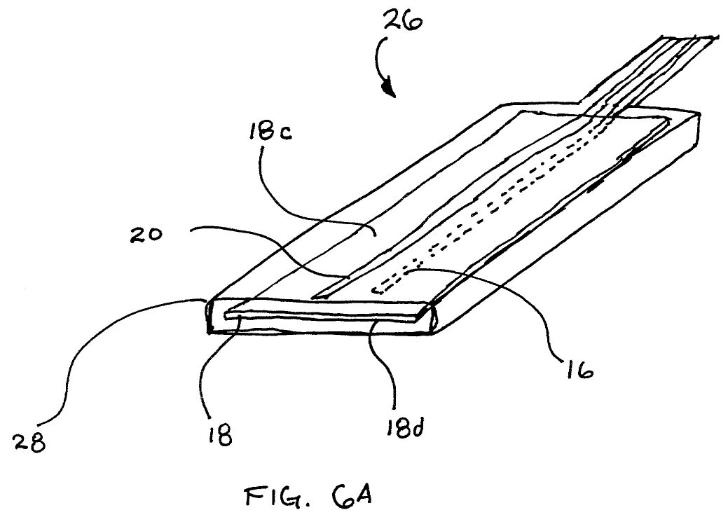

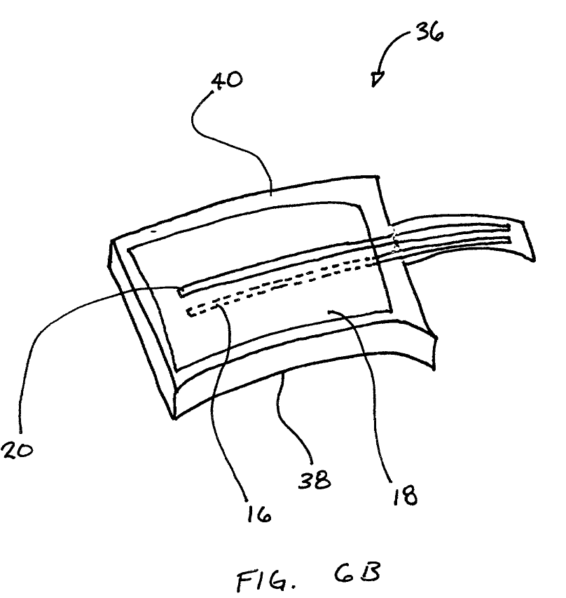

In another embodiment, shown generally in FIG. 6B, both film 14 and 22 have a different CTE with respect to each other, but both film 14 and 22 do not have a CTE that is the same as that of wafer 18. With this embodiment, the initial compressive stress placed on the wafer 18 at the concave surface 38, which has a film of greater CTE than the film of convex surface 40, is greater than the initial compressive stress at the convex surface 40, resulting in the flexible piezoelectric composite device 36 having an arcuate or curved shape.

Preferably, the CTE of each of the non-conductive films is “substantially greater” than that of wafer 18. A “substantially greater” CTE for the non-conductive films 14 and 22, as compared to the wafer means a ratio such that the heating and cooling of the non-conductive films during the step for consolidating results in a greater shrinkage of the films 14 and 22 than of the wafer 18 and accordingly places a substantial initial compressive stress on the wafer.

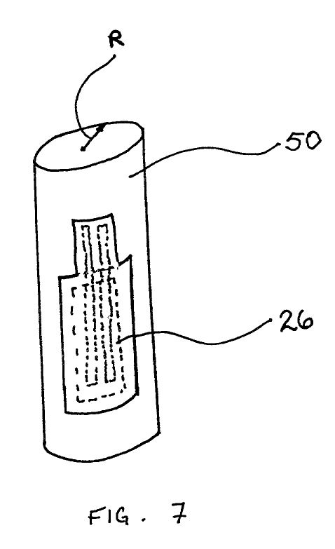

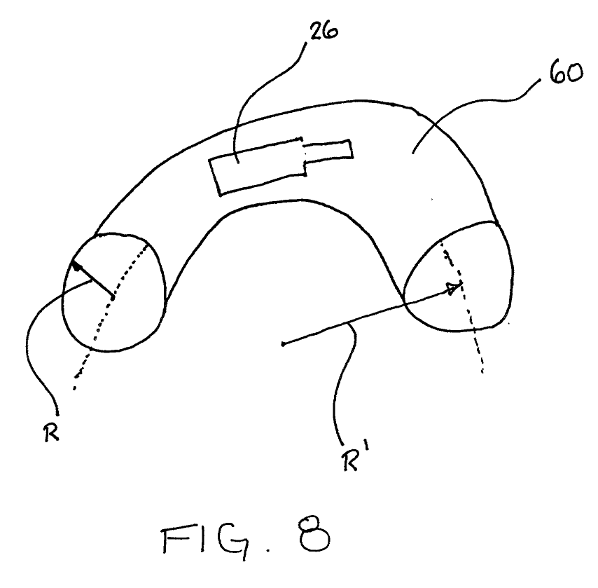

The encapsulation of leads 16 and 20 and the substantial initial compressive stress on wafer 18 during the step for consolidating results in a highly flexible piezoelectric device 26 having a significantly greater degree of flexibility than piezoelectric composite devices fabricated according to the aforementioned related art methods. While the term “highly flexible” is relative, it will be understood in this context that the device 26 is capable of being bent in the region of the piezoelectric wafer around highly or sharply curved surfaces. Examples of the various highly or sharply curved surfaces that device 26 can be flush-mounted or wrapped around are generally shown in FIGS. 7 and 8 and include a two-dimensional curved surface 50 or a three-dimensional curved surface 60, each having a radius of curvature R.

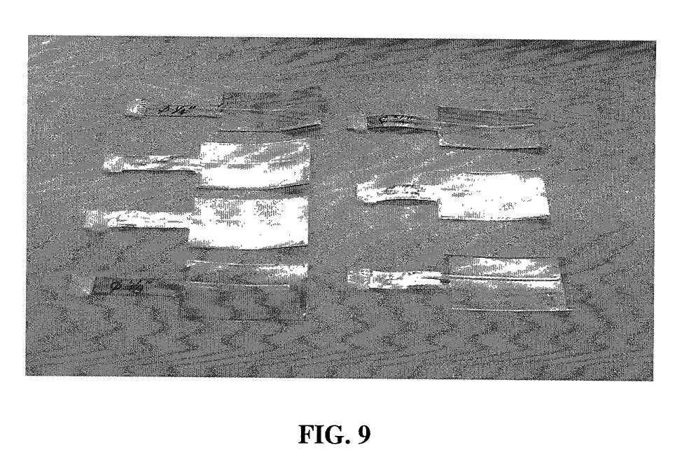

In particular, seven piezoelectric devices, as shown in FIG. 9, were made in accordance to the methods of the present invention and were tested to determine the effect of wrapping the devices around surfaces having different radii of curvature. A table of the different radii and the result of the testing are indicated in the chart below:

| Example | Radius (in) | Result |
|---|---|---|
| FP-101 | 1.00 | Functional |
| FP-102 | 0.88 | Functional |
| FP-103 | 0.75 | Functional |
| FP-104 | 0.63 | Functional |
| FP-105 | 0.50 | Functional |
| FP-106 | 0.38 | Functional |
| FP-107 | 0.25 | Functional |

From this test it has been determined that device 26 is capable of being wrapped in the area of the piezoelectric wafer around a sharply curved surface having a radius of curvature R of 0.25 inches or more.

The method of the present invention is suitable for batch production wherein a plurality of piezoelectric composite devices is fabricated simultaneously in accordance with the present invention.

Although only a few exemplary embodiments of this invention have been described in detail above, those skilled in the art will readily appreciate that many modifications are possible in the exemplary embodiments without materially departing from the novel teachings and advantages of this invention. Accordingly, all such modifications are intended to be included within the scope of this invention as defined in the following claims. In the claims, means-plus-function clauses are intended to cover the structures described herein as performing the recited function and not only structural equivalents, but also equivalent structures. Thus, although a nail and a screw may not be structural equivalents in that a nail employs a cylindrical surface to secure wooden parts together, whereas a screw employs a helical surface to secure wooden parts together, whereas a screw employs a helical surface, in the environment of fastening wooden parts, a nail and a screw may be equivalent structures.

What is claimed is:

1. A method of fabricating a piezoelectric composite device, comprising steps for:
providing a first layer of electrically non-conductive film;
disposing a first electrically conductive lead over the first layer of electrically non-conductive film;
disposing a piezoelectric wafer over the first electrically conductive lead and the first layer of electrically non-conductive film;
disposing a second electrically conductive lead over the piezoelectric wafer;
disposing a second layer of electrically non-conductive film over the second electrically conductive lead and the wafer;
retaining the films, leads and the wafer in predetermined positions, wherein the layers of film, the electrically conductive leads, and the wafer form a laminate assembly; and
consolidating the laminate assembly into a highly flexible piezoelectric composite device, wherein the first and second layers of electrically non-conductive film each have a predetermined coefficient of thermal expansion that is substantially greater than the predetermined coefficient of thermal expansion of the piezoelectric wafer.

2. The method according to claim 1 wherein the step for retaining comprises:
providing a first layer of electrically non-conductive adhesive tape having at least one adhesive side;
thereafter, disposing the first layer of electrically non-conductive film over the at least one adhesive side of the film; and
disposing a second layer of electrically non-conductive adhesive tape having at least one adhesive side over the second electrically non-conductive film such that the at least one adhesive side of the second layer of electrically non-conductive tape contacts the second electrically non-conductive film.

3. The method according to claim 2 further comprising removing the first and second layers of electrically non-conductive tape after the step for consolidating.

4. The method according to claim 1 wherein the step for consolidating the laminate assembly comprises:
bagging the laminate assembly with a third electrically non-conductive material;
providing a pressure chamber;
inserting the bagged laminate assembly into the chamber;
controlling the chamber to provide a predetermined pressure at a predetermined temperature;
venting gasses within the bagged laminate assembly;
maintaining the predetermined pressure and temperature for a predetermined amount of time; and
controlling the chamber to release the vacuum and reduce the pressure and to reduce the temperature to ambient temperature.

5. The method according to claim 4 wherein the step of bagging comprises the steps of:
providing a substantially flat plate;
placing the laminate assembly on the plate; and
covering the laminate assembly with the third electrically non-conductive material and sealing the material to the periphery of the plate to form an airtight seal.

6. The method according to claim 5 wherein the step of bagging further comprises the step of forming an opening in the third electrically non-conductive material to allow venting of gasses.

7. The method according to claim 1 wherein the step for consolidating comprises vacuum sealing the laminate assembly.

8. The method according to claim 1 wherein each layer of electrically non-conductive film is a polyimide film.

9. The method according to claim 1 wherein each of the layers of tape and film has a width and wherein (i) the wafer has a first widthwise end and a second widthwise end, (ii) the width of first layer of film is less than the width of the first tape, (iii) the first electrically conductive lead contacts a portion of the wafer that is in proximity to the first widthwise end of the wafer, (iv) the second electrically conductive lead contacts a portion of the wafer that is in proximity to the second widthwise end of the wafer, and (v) the width of the second layer of electrically non-conductive tape is greater than the second layer of electrically non-conductive film.

10. The method according to claim 1 wherein each of the layers of tape and film has a length and wherein (i) the length of first layer of tape is greater than the length of the first layer of film, (ii) the length of the first layer of film is greater than the length of the first conductive lead, (iii) the length of the first layer of film is greater than the length of the wafer, (iv) the length of the second layer of film is greater than the length of the wafer, (v) the length of the second layer of film is greater than the second conductive lead, and (vi) the length of the second layer of tape is greater than the length of the second layer of film.

11. The method according to claim 1 wherein the wafer has a predetermined coefficient of thermal expansion and each of the electrically non-conductive films has a different predetermined coefficient of thermal expansion wherein none of the coefficients of thermal expansion of the films are the same as the predetermined coefficient of thermal expansion of the wafer.

12. The method according to claim 1 wherein the step of providing comprises the steps of:
providing a mold that has a substantially flat surface; and
thereafter, disposing a first layer of electrically non-conductive adhesive tape on the flat surface such that an adhesive side of the tape faces up.

13. A method of fabricating a piezoelectric composite device, comprising the steps for:
providing a substantially flat surface;
disposing a first layer of electrically non-conductive adhesive tape on the surface such that the adhesive side of the tape faces up, the layer of tape having a predetermined width;
disposing a first layer of electrically non-conductive film over the first layer of tape, the layer of film having a second predetermined width that is less than the first predetermined width, the layer of film having a first widthwise end and a second widthwise end;
disposing a first electrically conductive lead over the first layer of electrically non-conductive film, the lead contacting a portion of the film that is in proximity to the first widthwise end of the layer of film;
disposing a piezoelectric wafer over the first electrically conductive lead and the first layer of electrically non-conductive film, the wafer having a third predetermined width that is less than the second predetermined width;
disposing a second electrically conductive lead over the piezoelectric wafer, the second conductive lead being in contact with a portion of the wafer that is in proximity to the second widthwise end of the wafer;
disposing a second electrically non-conductive film over the second electrically conductive lead and the wafer, the second electrically non-conductive film having a fourth predetermined width that is generally the same as the second predetermined width;
disposing a second layer of electrically non-conductive adhesive tape over the second electrically non-conductive film such that the adhesive side of the tape contacts the second electrically non-conductive film, the second layer of tape having a fifth predetermined width that is generally the same as the first predetermined width;
wherein the layers of electrically non-conductive tape and film, the electrically conductive leads, and the wafer form a laminate assembly,
consolidating the laminate assembly; and
thereafter, removing the first and second layers of tape after the laminate assembly is consolidated.

14. The method according to claim 1 wherein the step for consolidating the laminate assembly comprises use of a hot press.

15. The method according to claim 14 wherein the step for consolidating the laminate assembly comprises:
cleaning the platens of the hot press and aligning the platens to be flat and substantially parallel;
covering the bottom platen of the hot press with a high temperature cloth;
placing the laminate assembly on the high temperature cloth;
covering the laminate assembly with a second piece of high temperature cloth;
covering the second piece of high temperature cloth with a rubber sheet;
heating the laminate assembly to a predetermined temperature that is above the glass transition temperature of the first and second layer of electrically non-conductive film and is below the Curie temperature of the piezoelectric wafer;
applying a pre-determined amount of pressure;
holding the pre-determined temperature and pressure for a pre-determined amount of time;
cooling the pressed assembly to ambient room temperature;
removing the applied, pre-determined pressure; and
removing the consolidated laminate assembly from the hot press.

16. The method according to claim 15 wherein the pre-determined temperature is 325° C.

17. The method according to claim 15 wherein the pre-determined amount of pressure is 300 psi.

18. A piezoelectric composite device made according to the method of claim 1.

19. A piezoelectric composite device made according to the method of claim 4.

20. A piezoelectric composite device made according to the method of claim 14.

21. A piezoelectric composite device made according to the method of claim 15.

22. An apparatus comprising:
a piezoelectric wafer having a first electroded surface and a second electroded side opposite to said first electroded surface;
a first electrically conductive ribbon lead positioned over and in electrical contact with the first electroded surface of the piezoelectric wafer;
a second electrically conductive ribbon lead positioned over and in electrical contact with the second electroded surface of the piezoelectric wafer; and
a layer of curable, electrically non-conductive material, the layer of material surrounding the piezoelectric wafer and the first and second electrically conductive ribbon leads, the layer of curable, electrically non-conductive material having a coefficient of thermal expansion that is substantially greater than the coefficient of thermal expansion of the piezoelectric wafer, the layer of curable, electrically non-conductive material compressing the piezoelectric wafer to such a degree that the piezoelectric wafer becomes highly flexible.

23. The apparatus according to claim 22 wherein the first electroded surface comprises a thin surface deposit of nickel.

24. The apparatus according to claim 22 wherein the second electroded surface comprises a thin surface deposit of nickel.

25. The apparatus according to claim 22 wherein the first electrically conductive lead is made of nickel.

26. The apparatus according to claim 22 wherein the second electrically conductive lead is made of nickel.

27. The apparatus according to claim 22 wherein the layer of curable, electrically non-conductive film is a thermoplastic polyimide.

28. The apparatus according to claim 22 wherein the piezoelectric wafer is made of lead zirconate titanate.

29. An apparatus comprising:
a piezoelectric wafer having a first electroded surface and a second electroded side opposite to said first electroded surface;
a first electrically-conductive ribbon lead positioned over and in electrical contact with the first electroded surface of the piezoelectric wafer;
a second electrically-conductive ribbon lead positioned over and in electrical contact with the second electroded surface of the piezoelectric wafer; and
a layer of curable, electrically non-conductive material, the layer of material surrounding the piezoelectric wafer and the first and second electrically conductive ribbon leads, the layer of curable, electrically non-conductive material having a coefficient of thermal expansion that is substantially greater than the coefficient of thermal expansion of the piezoelectric wafer, the layer of curable, electrically non-conductive material compressing the piezoelectric wafer to such a degree that the piezoelectric wafer becomes capable of being wrapped around a highly curved surface.

30. The apparatus according to claim 29 wherein the first electroded surface comprises a thin surface deposit of nickel.

31. The apparatus according to claim 29 wherein the second electroded surface comprises a thin surface deposit of nickel.

32. The apparatus according to claim 29 wherein the first electrically conductive lead is made of nickel.

33. The apparatus according to claim 29 wherein the second electrically conductive lead is made of nickel.

34. The apparatus according to claim 29 wherein the layer of curable, electrically non-conductive film is a thermoplastic polyimide.

35. The apparatus according to claim 29 wherein the piezoelectric wafer is made of lead zirconate titanate.

36. An apparatus comprising:
a piezoelectric wafer having a first electroded surface and a second electroded side opposite to said first electroded surface;
a first electrically-conductive ribbon lead positioned over and in electrical contact with the first electroded surface of the piezoelectric wafer;
a second electrically-conductive ribbon lead positioned over and in electrical contact with the second electroded surface of the piezoelectric wafer; and
a layer of curable, electrically non-conductive material, the layer of material surrounding the piezoelectric wafer and the first and second electrically conductive ribbon leads, the layer of curable, electrically non-conductive material having a coefficient of thermal expansion that is substantially greater than the coefficient of thermal expansion of the piezoelectric wafer, the layer of curable, electrically non-conductive material compressing the piezoelectric wafer to such a degree that the piezoelectric wafer is capable of being sharply bent.

37. The apparatus according to claim 37 wherein the first electroded surface comprises a thin surface deposit of nickel.

38. The apparatus according to claim 37 wherein the second electroded surface comprises a thin surface deposit of nickel.

39. The apparatus according to claim 37 wherein the first electrically conductive lead is made of nickel.

40. The apparatus according to claim 37 wherein the second electrically conductive lead is made of nickel.

41. The apparatus according to claim 37 wherein the layer of curable, electrically non-conductive film is a thermoplastic polyimide.

42. The apparatus according to claim 37 wherein the piezoelectric wafer is made of lead zirconate titanate.
